(19) United States
(12) Patent Application Publication
(10) Pub. No.: US 2025/0031496 A1
(43) Pub. Date: Jan. 23, 2025

(54) LIGHT EMISSION DEVICE AND IMAGE DISPLAY APPARATUS

(71) Applicant: SONY GROUP CORPORATION, Tokyo (JP)

(72) Inventor: Mikio TAKIGUCHI, Tokyo (JP)

(73) Assignee: SONY GROUP CORPORATION, Tokyo (JP)

(21) Appl. No.: 18/707,097

(22) PCT Filed: Oct. 18, 2022
(86) PCT No.: PCT/JP2022/038786

§ 371 Date: May 2, 2024

(30) Foreign Application Priority Data
Nov. 12, 2021 (JP) 2021-185012

(51) Int. Cl. H01L 33/50; H01L 25/075; H01L 33/60

(52) U.S. Cl. CPC H01L 33/508; H01L 33/504; H01L 33/60; H01L 25/0753; H01L 2933/0091

(57) ABSTRACT

A light emission device according to an embodiment of the present disclosure includes a light source unit and a wavelength conversion layer. The light source unit has a light emission surface and emits first light from the light emission surface. The wavelength conversion layer is disposed on a side of the light emission surface of the light source unit, has a first surface disposed to face the light emission surface and a second surface disposed on an opposite side of the first surface, and includes a plurality of wavelength conversion materials that converts the first light into second light in a different wavelength band and a plurality of scattering particles. The wavelength conversion layer has a lower absorption coefficient of the first light in the vicinity of the first surface than in the vicinity of the second surface.

### TECHNICAL FIELD

The present disclosure relates to a light emission device and an image display apparatus including the same.

### BACKGROUND ART

For example, Patent Literature 1 discloses a light-emitting diode (LED) device that includes a wavelength conversion member. The wavelength conversion member includes a first resin layer and a second resin layer stacked in this order on an LED element. In the first resin layer, only light-scattering materials are dispersed. In a second resin layer, light-scattering materials and quantum dots are dispersed.

### CITATION LIST

### Patent Literature

PTL 1: Japanese Unexamined Patent Application Publication No. 2020-43353

### SUMMARY OF THE INVENTION

Meanwhile, a light emission device including quantum dots as a wavelength conversion material is required to have both of light extraction efficiency and reliability.

It is desirable to provide a light emission device and an image display apparatus that makes it possible to have both of the light extraction efficiency and the reliability.

A light emission device according to an embodiment of the present disclosure includes a light source unit and a wavelength conversion layer. The light source unit has a light emission surface and emits first light from the light emission surface. The wavelength conversion layer is disposed on a side of the light emission surface of the light source unit, has a first surface disposed to face the light emission surface and a second surface disposed on an opposite side of the first surface, includes a plurality of wavelength conversion materials that converts the first light into second light in a different wavelength band and a plurality of scattering particles, and has a lower absorption coefficient of the first light in the vicinity of the first surface than in the vicinity of the second surface.

An image display apparatus according to an embodiment of the present disclosure includes the light emission device according to the embodiment.

In the light emission device according to the embodiment of the present disclosure and the image display apparatus according to the embodiment of the present disclosure, the wavelength conversion layer includes the plurality of wavelength conversion materials that converts the first light emitted from the light source unit into the second light in the different wavelength band and the plurality of scattering particles. The wavelength conversion layer has a lower absorption coefficient of the first light in the vicinity of a surface on the side of the light source unit (the first surface) than in the vicinity of a light extraction surface (the second surface). This reduces a rate of absorption of excitation light in the vicinity of the light source unit.

### BRIEF DESCRIPTION OF DRAWING

FIG. 1 is a cross-sectional schematic view of a configuration example of a light emission device according to one embodiment of the present disclosure.

FIG. 2 is a characteristic diagram illustrating the result of a simulation regarding a relationship between the thickness of a QD layer that includes no scattering particle and light extraction efficiency according to an Example and Comparative Examples 1 and 2.

FIG. 3 is a characteristic diagram illustrating a result of simulation regarding a relationship between a position in a wavelength conversion layer and the amount of absorption of excitation light per unit length according to Example and Comparative Examples 1 and 2.

FIG. 4 is a schematic cross-sectional view of a configuration example of a light emission unit including the plurality of light emission devices illustrated in FIG. 1.

FIG. 5 is a schematic cross-sectional view of another configuration example of the light emission unit including the plurality of light emission devices illustrated in FIG. 1.

FIG. 6 is a schematic cross-sectional view of a configuration example of a light emission device according to Modification Example 1 of the present disclosure.

FIG. 7 is a schematic cross-sectional view of a configuration example of a light emission device according to Modification Example 2 of the present disclosure.

FIG. 8 is a schematic cross-sectional view of a configuration example of a light emission device according to Modification Example 3 of the present disclosure.

FIG. 9 is a schematic cross-sectional view of a configuration example of a quantum dot phosphor.

FIG. 10 is a schematic cross-sectional view of a configuration example of a light emission device according to Modification Example 4 of the present disclosure.

FIG. 11 is a schematic cross-sectional view of a configuration example of a light emission device according to Modification Example 5 of the present disclosure.

FIG. 12 is a schematic cross-sectional view of a configuration example of a light emission device according to Modification Example 6 of the present disclosure.

FIG. 13 is a schematic cross-sectional view of a configuration example of a light emission device according to Modification Example 7 of the present disclosure.

FIG. 14 is a schematic cross-sectional view of a configuration example of a light emission device according to Modification Example 8 of the present disclosure.

FIG. 15 is a schematic cross-sectional view of a configuration example of a light emission unit according to Modification Example 9 of the present disclosure.

FIG. 16 is a schematic cross-sectional view of a configuration example of a light emission unit according to Modification Example 10 of the present disclosure.

FIG. 17 is a schematic cross-sectional view of a configuration example of a light emission unit according to Modification Example 11 of the present disclosure.

FIG. 18 is a schematic cross-sectional view of a configuration example of a wavelength conversion layer according to Modification Example 12 of the present disclosure.

FIG. 19 is a schematic cross-sectional view of a configuration example of a light emission device according to Modification Example 13 of the present disclosure.

FIG. 20 is a perspective view of a configuration example of an image display apparatus according to Application Example 1 of the present disclosure.

FIG. 21 is a schematic diagram illustrating an exemplary layout of the image display apparatus illustrated in FIG. 20.

FIG. 22 is a pixel circuit diagram of an active matrix drive system.

FIG. 23 is a perspective view of a configuration example of an image display apparatus according to Application Example 2 of the present disclosure.

FIG. 24 is a perspective view of a configuration of a mounting substrate illustrated in FIG. 23.

FIG. 25 is a perspective view of a configuration of a unit substrate illustrated in FIG. 24.

FIG. 26 is a diagram illustrating an example of an image display apparatus according to Application Example 3 of the present disclosure.

### MODES FOR CARRYING OUT THE INVENTION

Hereinafter, an embodiment of the present disclosure is described in detail with reference to the drawings. The following description is one specific example of the present disclosure, and the present disclosure is not limited to the following modes. In addition, the arrangement, dimensions, dimension ratios, and the like of components of the present disclosure are not limited to those illustrated in each drawing. Note that the description is made in the following order.
1. Embodiment (example of light emission device in which scattering particles are selectively dispersed on side of light extraction surface)
1-1. Configuration of Light Emission Device
1-2. Configuration of Light Emission Unit
1-3. Workings and Effect
2. Modification Example 1 (example in which concentrations of scattering particles varies between light source side and light extraction surface side)
3. Modification Example 2 (example in which concentrations of quantum dot phosphors varies between light source side and light extraction surface side)
4. Modification Example 3 (example in which configurations of quantum dot phosphors varies between light source side and light extraction surface side)
5. Modification Example 4 (example in which resin layer is provided between light source side and light extraction surface side)
6. Modification Example 5 (example in which region including only scattering particle is provided on light source unit side)
7. Modification Example 6 (example in which Cd-based quantum dot phosphor and Cd-free quantum dot phosphor are used)
8. Modification Example 7 (example in which concentration of scattering particles in in-plane direction is changed on light extraction surface side)
9. Modification Example 8 (example in which side surface of wavelength conversion layer is made as inclined surface)
10. Modification Example 9 (example of light emission unit in which microlens array is disposed on light extraction surface)
11. Modification Example 10 (another configuration example of wavelength conversion layer of blue light emission device)
12. Modification Example 11 (example of light emission unit in which color filter is disposed on light extraction surface)
13. Modification Example 12 (another structure example of wavelength conversion layer)
14. Modification Example 13 (example in which texture structure is disposed on light extraction surface)
15. Application Examples

### 1. Embodiment

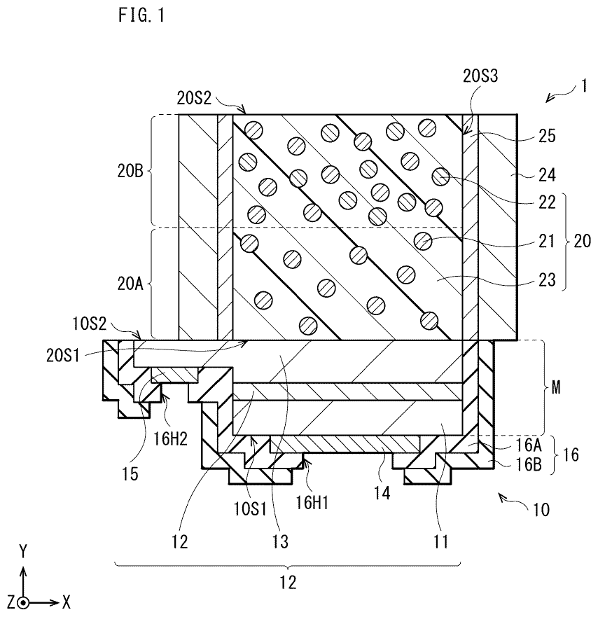

FIG. 1 schematically illustrates an example of a cross-sectional configuration of a light emission device (light emission device 1) according to an embodiment of the present disclosure.

The light emission device 1 is preferably used, for example, for a display pixel P of an image display apparatus (for example, image display apparatus 100, refer to FIG. 20).

The light emission device 1 according to the present embodiment includes a light source

unit 10 that emits excitation light EL, and a wavelength conversion layer 20 that is disposed on a side of a light emission surface (surface 10S2) of the light source unit 10, absorbs the excitation light EL, and emits light with a different wavelength. For example, in the wavelength conversion layer 20, a plurality of quantum dot phosphors 21 and a plurality of scattering particles 22 are dispersed in a resin 23, and the wavelength conversion layer 20 includes a first region 20A and a second region 20B in order from the side of the surface 10S2 of the light source unit 10. The first region 20A has a configuration in which only the plurality of quantum dot phosphors 21 is dispersed in the resin 23, and has an absorption coefficient of the excitation light EL lower than that of the second region 20B.

### 1-1. Configuration of Light Emission Device

The light source unit 10 corresponds to a specific example of a “light source unit” in the present disclosure. The light source unit 10 is a solid-state light emission device that emits light in a predetermined wavelength band from a top surface (light emission surface). The light source unit 10 is, for example, a light-emitting diode (LED) chip. The LED chip refers to a cut piece of a wafer used for crystal growth and does not refer to a package type covered with a molded resin or the like. The LED chip has a size equal to or greater than 1 μm and equal to or less than 100 μm, for example, and is a so-called micro-LED.

The light source unit 10 includes a first conductive type layer 11, an active layer 12, and a second conductive type layer 13 that are stacked in this order. A top surface of the second conductive type layer 13 serves as a light emission surface. The light source unit 10 has a pillar mesa portion M including the first conductive type layer 11 and the active layer 12 and includes a step including a recess portion from which the first conductive type layer 11 is exposed and a projection portion from which the second conductive type layer 13 is exposed, on a surface (surface 10S1) on an opposite side of the light emission surface. In the present embodiment, a surface, including the recess portion and the projection portion, on an opposite side of the light extraction surface 10S2 (side of surface 10S1) is assumed as a bottom surface. The light source unit 10 further includes a first electrode 14 that is electrically coupled to the first conductive type layer 11 and a second electrode 15 that is electrically coupled to the second conductive type layer 13. Each of the first electrode 14 and the second electrode 15 is provided on the side of the surface 10S1. Specifically, the first electrode 14 is disposed on the surface 10S1 of the first conductive type layer that is the recess portion of the bottom surface, and the second electrode 15 is disposed on the surface 10S1 of the second conductive type layer that is the projection portion of the bottom surface.

A side surface of the light source unit 10 including the first conductive type layer 11, the active layer 12, and the second conductive type layer 13 is covered with a laminated film 16 including an insulation film 16A and a reflection film 16B. For example, the laminated film 16 extends to peripheral edges of the first electrode 14 and the second electrode 15 and has openings 16H1 and 16H2 respectively on the first electrode 14 and the second electrode 15. That is, the first electrode and the second electrode are exposed outside through the openings 16H1 and 16H2, respectively.

A material of the first conductive type layer 11, the active layer 12, and the second conductive type layer 13 is appropriately selected in accordance with light in a desired wavelength band. In a case where a III-V compound semiconductor material is used, the light source unit 10 emits ultraviolet rays of which an emission wavelength is, for example, equal to or greater than 360 nm and equal to or less than 430 nm, or light in a blue band (blue light) of which an emission wavelength is, for example, equal to or greater than 430 nm and equal to or less than 500 nm. As the III-V compound semiconductor material, for example, an AlGaInN based material is exemplified. In addition, a ZnSe-based material or a ZnO-based material may be used. It is possible to form the active layer 12, for example, using a GaInN-based material.

It is to be noted that the light emitted from the light source unit 10 is not limited to the ultraviolet rays or the blue light, and may be, for example, infrared rays or light in a red band (red light). In that case, as a III-V compound semiconductor material that emits the infrared rays, for example, an AlGaInAs-based material is exemplified. As a III-V compound semiconductor material that emits the red light, for example, an AlGaInP-based material is exemplified.

The first electrode 14 is in contact with the first conductive type layer 11 and electrically coupled to the first conductive type layer 11. That is, the first electrode 14 is brought into ohmic contact with the first conductive type layer 11. The first electrode 14 is, for example, a metal electrode and is formed as a multi-layer film (Ni/Au) including nickel (Ni) and gold (Au). In addition, the first electrode 14 may include a transparent conductive material such as indium-tin oxide (ITO), for example.

The second electrode 15 is in contact with the second conductive type layer 13 and is electrically coupled to the second conductive type layer 13. That is, the second electrode 15 is brought into ohmic contact with the second conductive type layer 13. The second electrode 15 is, for example, a metal electrode, and is formed as a multi-layer film (Ti/Al) including titanium (Ti) and aluminum (Al) or a multi-layer film (Cr/Au) including chromium (Cr) and Au. In addition, the second electrode 15 may include a transparent conductive material such as ITO, for example.

The laminated film 16 is formed from the side surface of the light source unit 10 to the bottom surface as described above. Each of the insulation film 16A and the reflection film 16B is a thin film, and it is possible to form the insulation film 16A and the reflection film 16B through a thin-film formation process, for example, CVD, vapor deposition, or sputtering.

The insulation film 16A electrically isolates the reflection film 16B from the first conductive type layer 11, the active layer 12, and the second conductive type layer 13. It is preferable to form the insulation film 16A using a transparent material with respect to light emitted from the active layer 12. As such a material, for example, SiO₂, Si₂N₃, Al₂O₃, TiO₂, and TiN are exemplified. The insulation film 16A has a thickness of, for example, about 50 nm to 1 μm.

The reflection film 16B reflects light emitted from an active layer 122. The reflection film 16B is provided with the insulation film 16A on its inner side. Specifically, the reflection film 16B extends to the side surface and the bottom surface of the light source unit 10, and is formed, for example, to a position slightly backward from an end portion of the insulation film 16A in the openings 16H1 and 16H2 of the insulation film 16A. As a result, the reflection film 16B is isolated and separated (electrically separated) from the first conductive type layer 11, the active layer 12, the second conductive type layer 13, the first electrode 14, and the second electrode 15, by the insulation film 16A. It is preferable to use a material that reflects the light emitted from the active layer 12, as a material of the reflection film 16B. Such a material includes, for example, Ti, Al, silver (Ag), copper (Cu), Au, Ni, or an alloy thereof. The reflection film 16B has a thickness of, for example, about 50 nm to 1 μm.

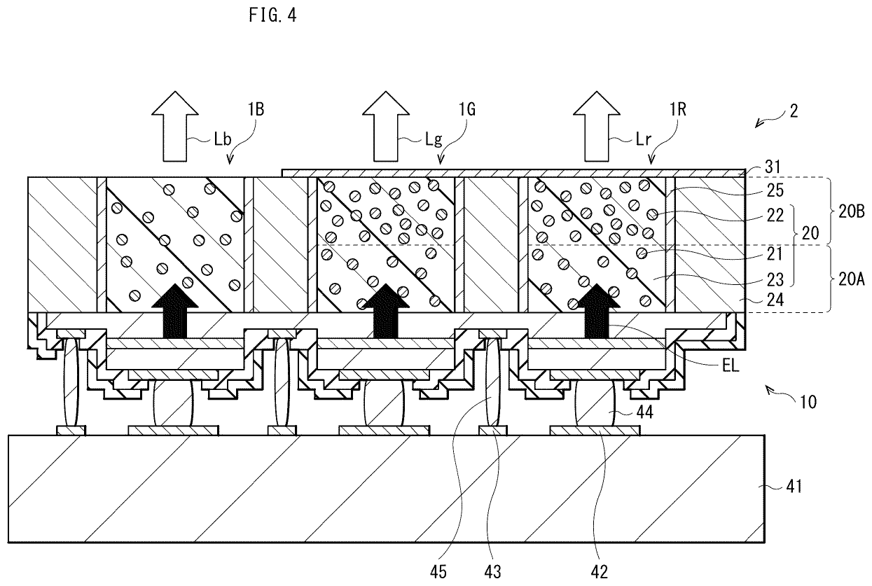

It is to be noted that an insulation film may be further formed on the reflection film 16B. In that case, it is preferable that the insulation film be formed on the first electrode 14 and the second electrode 15 so as to extend to the insulation film 16A and cover an end portion of the reflection film 16B. As a result, when the light emission device 1 (1B, 1G, and 1R) to be described later is mounted on a driving substrate 41, it is possible to prevent short circuit of bumps 44 and 45 with respect to the reflection film 16B. The bump 44 joins a pad electrode 42 on the driving substrate 41 and the first electrode 14, and the bump 45 joins a pad electrode 43 on the driving substrate 41 and the second electrode 15 (refer to FIG. 4).

The wavelength conversion layer 20 corresponds to a specific example of a “wavelength conversion layer” in the present disclosure. The wavelength conversion layer 20 is disposed on the side of the surface 10S2 of the light source unit 10 and converts the light emitted from the light source unit 10 into light in a desired wavelength band (for example, red light Lr, green light Lg, and blue light Lb). The wavelength conversion layer 20 has a surface 20S1 and a surface 20S2 as a pair of opposed surfaces. The surface 20S1 corresponds to a “first surface” in the present disclosure and is disposed to face the surface 10S2 of the light source unit 10. The surface 20S2 corresponds to a “second surface” in the present disclosure and serves as a surface from which wavelength-converted light is extracted.

In the wavelength conversion layer 20, the plurality of quantum dot phosphors 21 and the plurality of scattering particles 22 are dispersed in the resin 23, as described above.

The quantum dot phosphor 21 corresponds to a specific example of a “wavelength conversion material” of the present disclosure. The quantum dot phosphor 21 absorbs the light emitted from the light source unit 10 as the excitation light EL and emits fluorescence. Specifically, for example, the quantum dot phosphor 21 is a particle-shaped phosphor that emits fluorescence in a blue wavelength band equal to or greater than 430 nm and equal to or less than 500 nm, a green wavelength band equal to or greater than 500 nm and equal to or less than 550 nm, or a red wavelength band equal to or greater than 610 nm and equal to or less than 780 nm.

The largest factor that determines the fluorescence wavelength (fluorescence color) of the quantum dot phosphor is bandgap energy of a material included in the quantum dot. Therefore, it is desirable to select a material depending on a desired fluorescence color. For example, in a case where red fluorescence (red light Lr) is obtained, it is possible to select the quantum dot phosphor 21, for example, from among InP, GaInP, InAsP, CdSe, CdZnSe, CdTeSe, or CdTe. In a case where green fluorescence (green light Lg) is obtained, it is possible to select the quantum dot phosphor 21, for example, from among InP, GaInP, ZnSeTe, ZnTe, CdSe, CdZnSe, CdS, or CdSeS. In a case where blue fluorescence (blue light Lb) is obtained, it is possible to select the quantum dot phosphor 21 from among ZnSe, ZnTe, ZnSeTe, CdSe, CdZnSe, CdS, CdZnS, or CdSeS, for example. It is to be noted that, the quantum dot phosphor 21 is not limited to the above, and for example, CuInSe₂, CuInS₂, CuInGaS, and AgInS₂ may be used. In addition, for example, perovskite nano phosphor including CsPb (Cl/Br)₃, CsPbBr₃, CsPb (I/Br)₃, and CsPbI₃ may be used.

Furthermore, it is possible for the quantum dot phosphor 21 to control the fluorescence color depending on a particle diameter thereof. For example, as the particle diameter decreases, the fluorescence wavelength is shortened. To obtain fluorescence with high color purity, it is desirable to select a quantum dot phosphor having a controlled particle diameter.

The quantum dot phosphor 21 has, for example, an average particle diameter of equal to or greater than 5 nm and equal to or less than 100 nm. For example, the quantum dot phosphor 21 has a core-shell structure that includes a core emitting light and having an average particle diameter of about 2 nm to 10 nm, and a shell covering and protecting the core. The shell includes a single or a plurality of layers. In addition, the shell may be covered with an inorganic film including silicon oxide (SiO₂) or aluminum oxide (Al₂O₃), for example. On a surface of the quantum dot phosphor 21, a large number of organic ligands are coordinated. With this organic ligands, when the quantum dot phosphors are mixed with a solvent, agglomeration of the quantum dot phosphors 21 is prevented, and dispersibility is improved.

To charge the quantum dot phosphor 21, for example, an ink-jet type dispenser or a needle-type dispenser that discharges or applies the quantum dot phosphor 21 is used depending on the viscosity of the resin 23 to be mixed with the quantum dot phosphor 21. This is classified into a plateless type printing method, and with this method, it is possible to selectively fill only a wall with the quantum dot phosphor 21. Therefore, it is possible to enhance use efficiency of the quantum dot phosphor 21. The quantum dot phosphor 21 may be applied to a determined place using screen printing or gravure printing technology that are plate printing methods. In addition, as in a spin coater or a PR method, for example, the quantum dot phosphor 21 may be applied to an entire substrate.

It is to be noted that, for the wavelength conversion layer 20, an inorganic phosphor or an organic phosphor may be used as the wavelength conversion material, instead of the quantum dot phosphor 21.

The scattering particle 22 improves light extraction efficiency by scattering the excitation light EL emitted from the light source unit 10 and the fluorescence emitted from the quantum dot phosphor 21 to change an incident angle of the fluorescence on the light extraction surface 20S2. Furthermore, the scattering particle 22 improves an absorption rate of the excitation light EL by increasing an effective optical path length of the excitation light EL. It is preferable for the scattering particle 22 to have a larger average particle diameter than the quantum dot phosphor 21 and a larger refractive index than the resin 23. For example, for the scattering particle 22, it is preferable to use a dielectric substance having a particle diameter of equal to or greater than 100 nm and equal to or less than 1000 nm. As a specific material of the scattering particle 22, for example, silicon oxide (SiO₂), titanium oxide (TiO₂), aluminum oxide (Al₂O₃), aluminum nitride (AlN), boron nitride (BN), and zinc oxide (ZnO) are exemplified.

It is to be noted that the scattering particle 22 may be, for example, an air bubble mixed into a filling material 123 or an agglomerated quantum dot phosphor 21.

The resin 23 is used to disperse the quantum dot phosphors 21 and the scattering particles 22, and it is possible to form the resin 23, for example, using a material having light transparency with respect to the excitation light EL. As a specific material of the resin 23, for example, an ultraviolet curing resin and a thermosetting resin are exemplified. Specific examples thereof include polypropylene, polyethylene, polystyrene, an AS resin, an ABS resin, a methacryl resin, polyvinyl chloride, polyacetal, polyamide, polycarbonate, modified polyphenylene ether, polybutylene telephthalate, polyethylene terephthalate, polysulfone, polyethersulfone, polyphenylene sulfide, polyamidimide, polymethylpentene, liquid crystal polymer, an epoxy resin, an acryl resin, a phenol resin, a urea resin, a melamine resin, a diallyl phthalate resin, an unsaturated polyester resin, polyimide, polyurethane, a silicone resin, and a mixture thereof. In addition, sol-gel glass may be used, for example.

It is to be noted that the resin 23 is not necessarily necessary, and the quantum dot phosphors 21 and the scattering particles 22 may be sealed in a hollow structure.

In the present embodiment, the wavelength conversion layer 20 includes the first region 20A and the second region 20B having the absorption coefficients of the excitation light EL different from each other, in order from the side of the surface 10S2 of the light source unit 10. The first region 20A does not include the plurality of scattering particles 22 in the resin 23 and has a configuration in which only the plurality of quantum dot phosphors 21 is dispersed. The second region 20B has a configuration in which both of the plurality of quantum dot phosphors 21 and the plurality of scattering particles 22 are dispersed in the resin 23. As a result, the first region 20A has the absorption coefficient of the excitation light EL lower than that of the second region 20B.

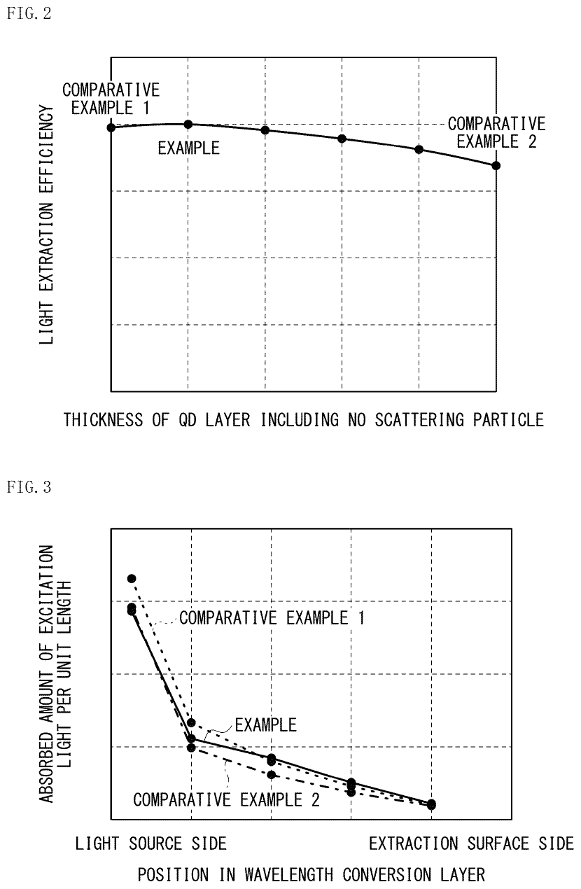

FIG. 2 illustrates the result of a simulation regarding a relationship between a thickness of a QD layer (wavelength conversion layer 20) that does not include the scattering particle 22 and the light extraction efficiency in Example and Comparative Examples 1 and 2. FIG. 3 illustrates the result of a simulation regarding a relationship between a position in the wavelength conversion layer 20 and the amount of absorbed excitation light per unit length in Example and Comparative Examples 1 and 2. Example is the light emission device 1 having the configuration described above. Comparative Example 1 is a light emission device in which the plurality of quantum dot phosphors 21 and the plurality of scattering particles are dispersed in the entire resin 23 included in the wavelength conversion layer 20, in a substantially uniform manner. Comparative Example 2 is a light emission device in which the plurality of scattering particles 22 is not included and only the plurality of quantum dot phosphors 21 is dispersed in the entire resin 23 included in the wavelength conversion layer 20 in a substantially uniform manner.

The excitation light EL having entered the wavelength conversion layer 20 is scattered by the scattering particles 22, which increases the optical path length. As a result, the rate of absorption of the excitation light EL in the wavelength conversion layer 20 increases in the wavelength conversion layer 20 (Example and Comparative Example 2) in which the plurality of quantum dot phosphors 21 and the plurality of scattering particles 22 are dispersed, as compared with a case where the plurality of scattering particles 22 is not included (Comparative Example 2). Furthermore, the fluorescence emitted from the quantum dot phosphor 21 is scattered by the scattering particles 22, which improves the light extraction efficiency (FIG. 2). On the other hand, when the optical path length of the excitation light EL in the wavelength conversion layer 20 increases, a temperature of the wavelength conversion layer 20 is increased due to heat generation of the quantum dot phosphor 21 caused by the absorption of the excitation light EL, and deterioration in the quantum dot phosphor 21 is likely to occur. The heat generation of the quantum dot phosphor 21 caused by the absorption of the excitation light EL becomes significant in the vicinity of the light source unit 10.

In contrast, in Example, the first region 20A in which the plurality of scattering particles 22 is not included in the resin 23 and only the plurality of quantum dot phosphors 21 is dispersed is provided on the side of the light source unit 10. As a result, a light density adjacent to the side of the light source unit 10 is reduced, and the amount of the absorbed excitation light EL per unit length is reduced to be substantially equal to Comparative Example 2 (FIG. 3). Therefore, the increase in the temperature in the vicinity of the side of the light source unit 10 is suppressed, and the deterioration in the quantum dot phosphor 2 is reduced.

A side surface (surface 20S3) of the wavelength conversion layer 20 is sealed, for example, with a side wall 24. As a material included in the side wall 24, for example, SiO₂, silicon (Si), a resist, a resin, and a metal material such as Cu or Al are exemplified.

A light reflection film 25 may be formed between the wavelength conversion layer 20 and the side wall 24. The light reflection film 25 reflects the excitation light EL emitted from the light source unit 10 and scattered with, for example, the scattering particles 22, and the fluorescence emitted from the quantum dot phosphor 21 into the wavelength conversion layer 20. It is preferable to form the light reflection film 25 using a material having a high reflection rate with respect to the excitation light EL and the fluorescence regardless of a light incident angle. As a material of the light reflection film 25, for example, a metal material such as gold (Au), Ag, aluminum (Al), or platinum (Pt) and a dielectric multi-layer film obtained by combining RiO₂, Ta₂O₅, TiO₂, SiN, SiO₂, and Al₂O₃ are exemplified.

### 1-2. Configuration of Light Emission Unit

In the image display apparatus 100 to be described later, the plurality of display pixels P is arranged in a display region 100A in a two-dimensional array. In each of the plurality of display pixels P, a light emission unit 2 including the plurality of light emission devices 1 is provided. FIG. 4 schematically illustrates a cross-sectional configuration of the light emission unit 2.

In the light emission unit 2, for example, the plurality of light emission devices 1 is disposed in line. For example, the light emission unit 2 has an elongated shape extending in a direction in which the plurality of light emission devices 1 is provided.

For example, the display pixel P of the image display apparatus 100 includes three color pixels Pr, Pg, and Pb corresponding to RGB, for example. In the color pixels Pr, Pg, and Pb, the light emission devices 1 that emit light in respectively corresponding wavelength bands are provided. FIG. 4 schematically illustrates an example of the cross-sectional configuration of the light emission unit 2. The light emission unit 2 includes light emission devices 1R, 1G, and 1B that emit light corresponding to the respective color pixels Pr, Pg, and Pb. That is, the light emission device 1R that emits the light in the red band (red light Lr) is provided in the color pixel Pr, the light emission device 1G that emits the light in the green band (green light Lg) is provided in the color pixel Pg, and the light emission device 1B that emits the light in the blue band (blue light Lb) is provided in the color pixel Pb. For example, in a case where the light emission unit 2 has an elongated shape in the direction in which the light emission device 1 is arranged, the light emission device 1R is disposed, for example, adjacent to a short side of the light emission unit 2, and the light emission device 1B is disposed, for example, adjacent to a short side different from the short side close to the light emission device 1B, of the short sides of the light emission unit 2. The light emission device 1G is disposed, for example, between the light emission devices 1R and 1B. It is to be noted that positions of the respective light emission devices 1R, 1G, and 1B are not limited to the above described positions.

Each of the light emission devices 1R, 1G, and 1B is mounted on the driving substrate 41 via the pad electrodes 42 and 43 and the bumps 44 and 45, for example. It is to be noted that mounting on the driving substrate 41 may be performed using another bonding method such as Cu—Cu bonding.

In each of the light emission devices 1R, 1G, and 1B, for example, the wavelength conversion layer 20 including the plurality of quantum dot phosphors 21 that wavelength-converts the excitation light EL into the light in the predetermined wavelength band is disposed on the light source unit 10 that emits the blue light as the excitation light EL. For example, in the wavelength conversion layer 20 of the light emission device 1R, the plurality of quantum dot phosphors 21 that emits red fluorescence and the plurality of scattering particles 22 are dispersed in the resin 23, and the excitation light EL emitted from the light source unit 10 is converted into the red light with the quantum dot phosphors 21, scattered with the scattering particles 22, and extracted as the red light Lr. In the wavelength conversion layer 20 of the light emission device 1G, the plurality of quantum dot phosphors 21 that emits green fluorescence and the plurality of scattering particles 22 are dispersed in the resin 23, and the excitation light EL emitted from the light source unit 10 is converted into the green light with the quantum dot phosphors 21, scattered with the scattering particles 22, and extracted as the green light Lg. In the wavelength conversion layer 20 disposed in the light emission device 1B, for example, only the scattering particles 22 are dispersed in the resin 23, and the excitation light EL emitted from the light source unit 10 is scattered with the scattering particles 22 and is extracted as the blue light Lb.

Furthermore, on the wavelength conversion layers 20 of the light emission devices 1R and 1G, an excitation light reflection film 31 may be provided as a wavelength selection layer that selectively reflects the excitation light EL. As a result, the excitation light EL emitted from the light extraction surface 20S2 of the wavelength conversion layer 20 is reduced, and it is possible to improve a color gamut. Furthermore, it is possible to improve a contrast of outside light. Furthermore, instead of the excitation light reflection film 31, a yellow filter that selectively absorbs the blue light may be disposed.

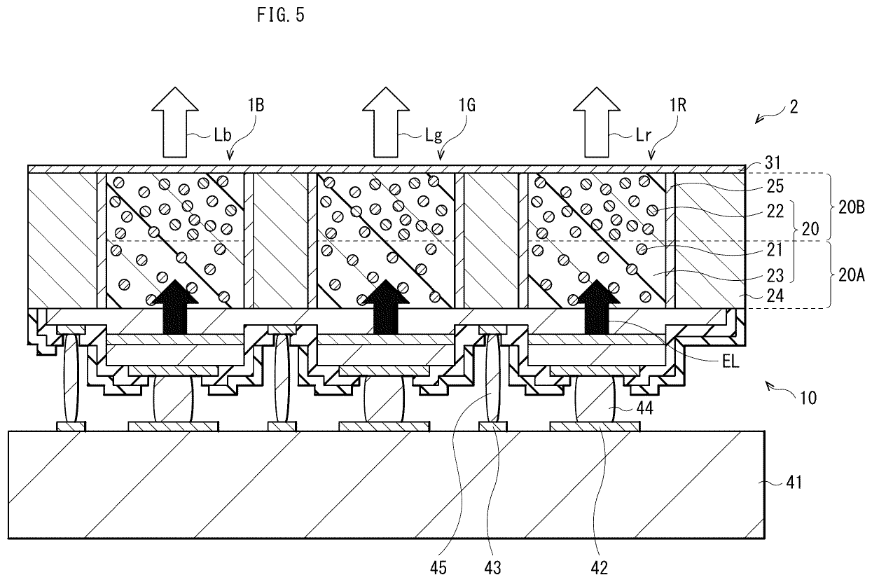

Furthermore, in a case where the light source unit 10 that emits ultraviolet rays as the excitation light EL is used, for example, as illustrated in FIG. 5, the wavelength conversion layer 20 in which the plurality of quantum dot phosphors 21 that emits blue fluorescence and the plurality of scattering particles 22 are disposed in the resin 23 is disposed, like the wavelength conversion layers 20 provided in the light emission devices 1R and 1G. As a result, in the light emission device 1B, the excitation light EL emitted from the light source unit 10 is converted into the blue light with the quantum dot phosphors 21, scattered with the scattering particles 22, and extracted as the blue light Lb. In a case where the light source unit 10 that emits ultraviolet rays as the excitation light EL is used, the excitation light reflection film 31 is also disposed on the light emission device 1B.

### 1-3. Workings and Effect

In the light emission device 1 according to the present embodiment, the wavelength conversion layer 20 includes the first region 20A and the second region 20B from the side of the light source unit 10. Only the plurality of quantum dot phosphors 21 is dispersed in the resin 23 in the first region 20A, and both of the plurality of quantum dot phosphors 21 and the plurality of scattering particles 22 are dispersed in the resin 23 in the second region 20B. The first region 20A has a lower absorption coefficient of the excitation light EL than the second region 20B. This reduces the rate of absorption of the excitation light EL in the vicinity of the light source unit 10. Hereinafter, a description is given in this regard.

In recent years, due to high color gamut of liquid crystal televisions, a product using a QD sheet for a backlight unit has been commercialized. In addition, a display device for augmented reality (AR) applications obtained by combining a blue LED array with a color conversion layer including the quantum dot (QD) has been developed. For the color conversion layer using the QD, a QD layer with high color conversion efficiency is required for high luminance and power saving. Regarding the color conversion efficiency of the QD layer, light extraction efficiency from the QD layer is also important as well as a QD quantum yield. For example, because fluorescence is isotopically emitted from the QD, high-angle components are totally reflected at an interface between the QD and air. This reduces fluorescence to be extracted in the air.

To solve this problem, a method for adding scattering substances to the QD layer is used. As a result, an effect of the total reflection at the interface between the QD and the air is reduced, and the light extraction efficiency is improved by changing an angle of the fluorescence. In addition, an advantage is also obtained that the rate of absorption of the excitation light increases due to the increase in the optical path length of the excitation light in the QD layer by adding the scattering substances. As a result, it is possible to improve the color conversion efficiency of the QD layer by adding the scattering substance to the QD layer.

On the other hand, there is also a problem caused by adding the scattering substance. An excitation light density in the QD layer is increased due to the increase in the optical path length of the excitation light, which lowers reliability. The reliability of the QD layer is lowered as the excitation light density and a temperature of the QD layer become higher. The light density is the highest in the vicinity of the LED because an intensity distribution of the excitation light in the QD layer is exponentially attenuated as being away from the LED, regardless of whether there is the scattering substance. Furthermore, even in a case where the rate of absorption of the excitation light is the same, a total amount of the absorbed excitation light increases as the intensity of the excitation light increases. This increases heat generation caused by an energy loss at the time of color conversion in the vicinity of the LED. For these reasons, a region in the vicinity of the LED in the QD layer has the highest light density and the highest temperature, and deterioration is thus large in the QD. In a case where the scattering substance is included, the rate of absorption of the excitation light in the vicinity of the LED becomes higher, which increases the temperature of the QD layer in the vicinity of the LED and lowers the reliability. An attainment luminance of a light emission element using the color conversion layer including the QD is often limited in accordance with the reliability. Accordingly, both of light extraction efficiency and reliability of a device structure are to be achieved in order to improve the luminance of the light emission device.

Whereas, as described above, an LED device has been proposed that includes a layer to which only the scattering substance is added (scattering substance layer) between the LED and the QD layer to which the scattering substance is added. In this method, the reliability is improved by uniformizing the excitation light in a lateral direction with the scattering substance between the LED and the QD layer or by expanding an area of the excitation light by increasing a distance between the LED and the QD layer. On the other hand, the excitation light from the LED is returned to the LED by the scattering substance layer, which lowers the amount of light incident on the QD layer. Therefore, the light extraction efficiency of both of the LED and the color conversion layer is lowered. In addition, in a case where a narrow pitch is required as in the AR applications, the angle of a QD side wall becomes vertical, which limits a light density reduction effect caused by increasing the distance between the LED and the QD.

Whereas, according to the present embodiment, the wavelength conversion layer 20 includes the first region 20A provided on the side of the light source unit 10, and the second region 20B provided on the side of the light extraction surface 20S2. In the first region 20A, only the plurality of quantum dot phosphors 21 is dispersed in the resin 23, and in the second region 20B, both of the plurality of quantum dot phosphors 21 and the plurality of scattering particles 22 are dispersed in the resin 23. As a result, the absorption coefficient of the excitation light EL in the vicinity of the light source unit 10 is lower than the absorption coefficient of the excitation light

EL in the vicinity of the light extraction surface 20S2, and the absorption rate of the excitation light EL in the vicinity of the light source unit 10 is reduced. That is, the heat generation and the deterioration in the quantum dot phosphor 21 are reduced in the vicinity of the light source unit 10.

As described above, according to the light emission device 1 of the present embodiment, it is possible to achieve both of the improvement in the light extraction efficiency and the improvement in the reliability.

Next, Modification Examples 1 to 13 of the present disclosure are described. It is to be noted that components corresponding to those in the light emission device 1 according to the above embodiment are denoted with the same reference numerals, and a description thereof is omitted.

### 2. Modification Example 1

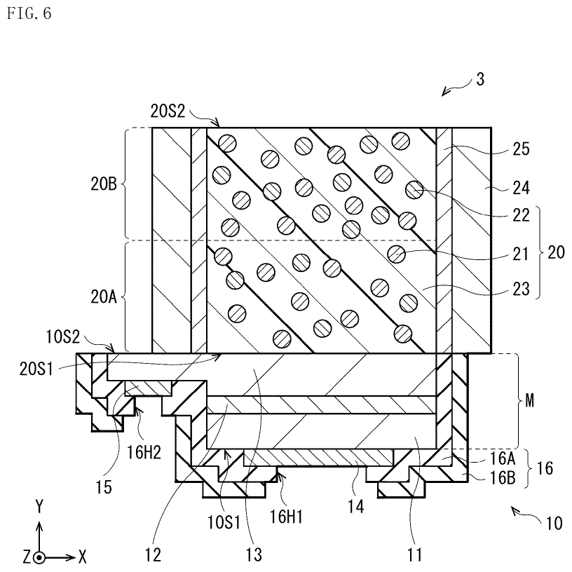

FIG. 6 schematically illustrates an example of a cross-sectional configuration of a light emission device (light emission device 3) according to Modification Example 1 of the present disclosure. The light emission device 3 is preferably used, for example, for the display pixel P of the image display apparatus (for example, image display apparatus 100), similarly to the light emission device 1 according to the above embodiment.

In the above embodiment, an example has been described in which only the plurality of quantum dot phosphors 21 is dispersed in the resin 23 in the first region 20A on the side of the light source unit 10, and the absorption coefficient of the excitation light EL in the vicinity of the light source unit 10 is lower than the absorption coefficient of the excitation light EL in the vicinity of the light extraction surface 20S2; however, the embodiment is a non-limiting example. For example, the plurality of scattering particles 22 may be dispersed in the first region 20A at a lower concentration than in the second region 20B.

In this way, in the present modification example, both of the plurality of quantum dot phosphors 21 and the plurality of scattering particles 22 are dispersed in the first region 20A, and the concentration of the plurality of scattering particles in the first region 20A is lower than the concentration of the plurality of scattering particles in the second region 20B. As a result, it is possible to obtain effects similar to those of the above embodiment.

### 3. Modification Example 2

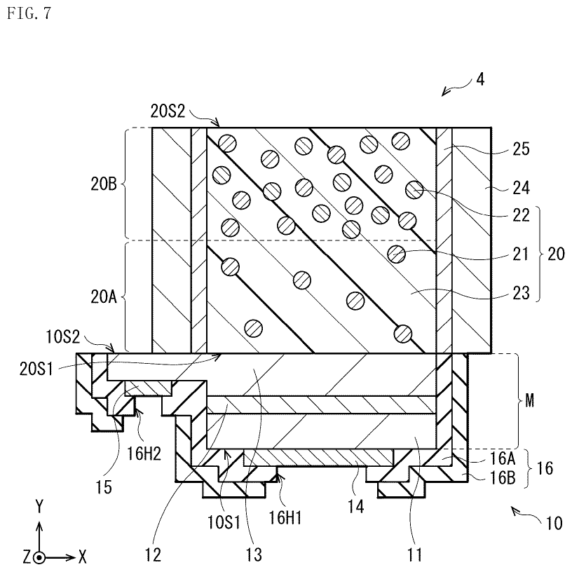

FIG. 7 schematically illustrates an example of a cross-sectional configuration of a light emission device (light emission device 4) according to Modification Example 2 of the present disclosure. The light emission device 4 is preferably used, for example, for the display pixel P of the image display apparatus (for example, image display apparatus 100), similarly to the light emission device 1 according to the above embodiment.

For example, a concentration of the plurality of quantum dot phosphors 21 dispersed in the first region 20A may be lower than a concentration of the plurality of quantum dot phosphors 21 dispersed in the second region 20B.

In this way, in the present modification example, the concentration of the plurality of quantum dot phosphors 21 in the first region 20A is lower than the concentration of the plurality of scattering particles in the second region 20B. As a result, as compared with the above-described embodiment, a heat generation amount in the first region 20A is further reduced, and it is possible to further improve the reliability. Furthermore, as compared with the above-described embodiment, it is possible to realize a higher luminance.

### 4. Modification Example 3

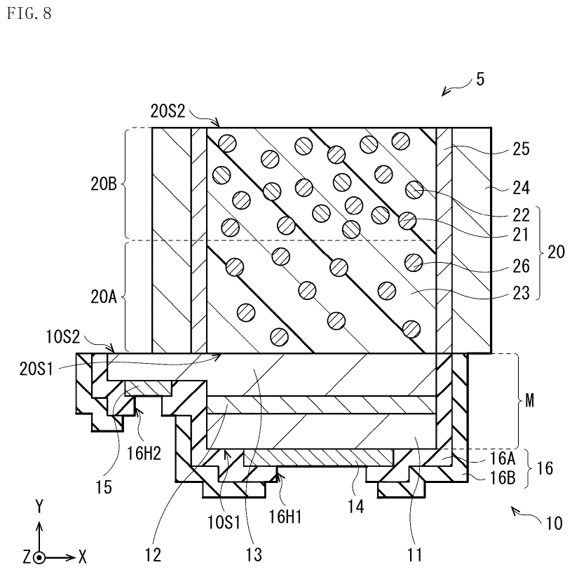

FIG. 8 schematically illustrates an example of a cross-sectional configuration of a light emission device (light emission device 5) according to Modification Example 3 of the present disclosure. The light emission device 5 is preferably used, for example, for the display pixel P of the image display apparatus (for example, image display apparatus 100), similarly to the light emission device 1 according to the above embodiment.

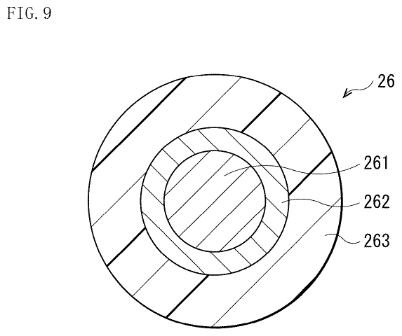

A plurality of quantum dot phosphors 26 having a different material, a different composition, or a different core-shell structure from that of the plurality of quantum dot phosphors 21 dispersed in the second region 20B may be dispersed in the first region 20A. For example, the quantum dot phosphors 2, having a lower absorption coefficient of the excitation light EL than the quantum dot phosphors 21 dispersed in the second region 20B are dispersed in the first region 20A. FIG. 9 schematically illustrates a cross-sectional configuration of the quantum dot phosphor 26. It is possible for the quantum dot phosphor 26 to control the absorption coefficient, for example, by changing the ratio of thicknesses of a core 261 and a shell A262 and a shell B263 covering the core 261.

In this way, in the present modification example, the quantum dot phosphors 26 having a lower absorption coefficient of the excitation light EL than the quantum dot phosphors 21 dispersed in the second region 20B are dispersed in the first region 20A. As a result, as compared with the above-described embodiment, the heat amount in the first region 20A is further reduced, and it is possible to further improve the reliability. Furthermore, as compared with the above-described embodiment, it is possible to realize a higher luminance.

### 5. Modification Example 4

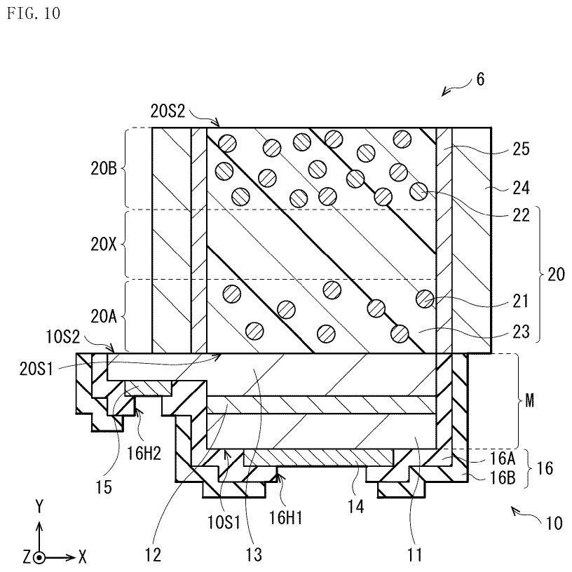

FIG. 10 schematically illustrates an example of a cross-sectional configuration of a light emission device (light emission device 6) according to Modification Example 4 of the present disclosure. This light emission device 6 is preferably used, for example, for the display pixel P of the image display apparatus (for example, image display apparatus 100), similarly to the light emission device 1 according to the above embodiment.

In the above embodiment, an example has been described in which only the plurality of quantum dot phosphors 21 is dispersed in the resin 23 in the first region 20A on the side of the light source unit 10 and the absorption coefficient of the excitation light EL adjacent to the light source unit 10 is made to be lower than the absorption coefficient of the excitation light EL adjacent to the light extraction surface 20S2. However, the embodiment is not limited to this. For example, a region 20X including only the resin 23 may be provided between the first region 20A in which only the plurality of quantum dot phosphors 21 is dispersed in the resin 23 and the second region 20B in which both of the plurality of quantum dot phosphors 21 and the plurality of scattering particles 22 are dispersed.

In this way, in the present modification example, the region 20X including only the resin 23 has been provided between the first region 20A and the second region 20B, and the first region 20A and the second region 20B have been spatially separated. As a result, it is possible to reduce an effect of the heat generation on the second region 20B, in the first region 20A. Therefore, as compared with the above-described embodiment, it is possible to further improve the reliability. Furthermore, as compared with the above-described embodiment, it is possible to realize a higher luminance.

### 6. Modification Example 5

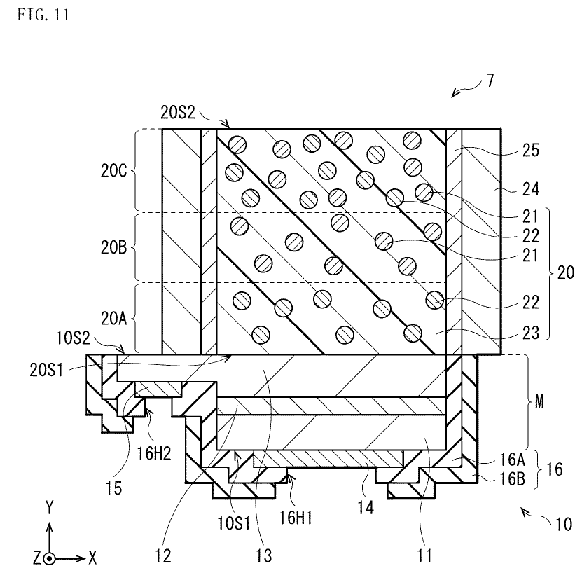

FIG. 11 schematically illustrates an example of a cross-sectional configuration of a light emission device (light emission device 7) according to Modification Example 5 of the present disclosure. The light emission device 7 is preferably used, for example, for the display pixel P of the image display apparatus (for example, image display apparatus 100), similarly to the light emission device 1 according to the above embodiment.

In the above-described embodiment, an example has been described in which the first region 20A in which only the plurality of quantum dot phosphors 21 is dispersed in the resin 23 and the second region 20B in which both of the plurality of quantum dot phosphors 21 and the plurality of scattering particles 22 are dispersed are provided in this order from the side of the light source unit 10. However, the wavelength conversion layer 20 is not limited to this configuration. For example, the wavelength conversion layer 20 is divided into, for example, three regions including the first region 20A, the second region 20B, and a third region 20C from the side of the light source unit 10. Only the plurality of scattering particles 22 is dispersed in the first region 20A, and the second region 20B and the third region 20C may have configurations similar to the respective configurations of the first region 20A and the second region 20B in the above-described embodiment.

In this way, in the present modification example, the wavelength conversion layer 20 is divided into, for example, the three regions including the first region 20A, the second region 20B, and the third region 20C from the side of the light source unit 10, and only the plurality of scattering particles 22 is dispersed in the first region 20A. As a result, the excitation light EL having entered from the light source unit 10 into the wavelength conversion layer 20 is equalized with the first region 20A. It is therefore possible to improve in-plane uniformity of the excitation light EL entering the second region 20B in which only the plurality of quantum dot phosphors 21 is dispersed in the resin 23. Therefore, as compared with the above-described embodiment, it is possible to further improve the reliability.

### 7. Modification Example 6

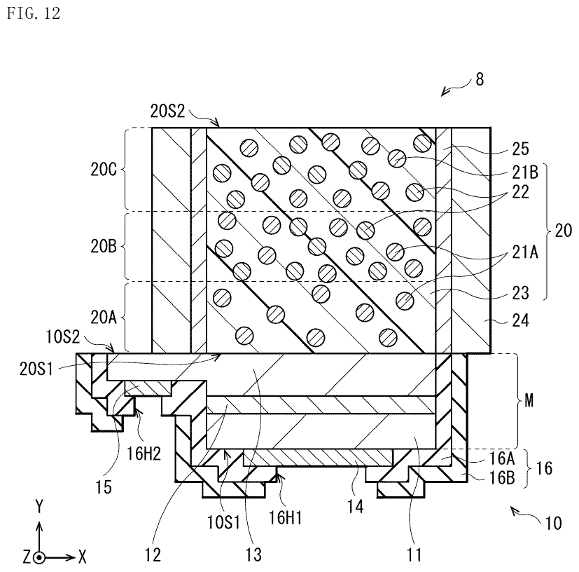

FIG. 12 schematically illustrates an example of a cross-sectional configuration of a light emission device (light emission device 8) according to Modification Example 6 of the present disclosure. The light emission device 8 is preferably used, for example, for the display pixel P of the image display apparatus (for example, image display apparatus 100), similarly to the light emission device 1 according to the above embodiment.

In the above embodiment, an example has been described in which the first region 20A in which only the plurality of quantum dot phosphors 21 is dispersed in the resin 23 and the second region 20B in which both of the plurality of quantum dot phosphors 21 and the plurality of scattering particles 22 are dispersed are provided in this order from the side of the light source unit 10. However, the wavelength conversion layer 20 is not limited to this configuration. For example, the third region 20C in which both of a plurality of quantum dot phosphors 21B and the plurality of scattering particles 22 are dispersed may be further provided on the second region 20B of the above-described embodiment.

In the present modification example, a plurality of quantum dot phosphors 21A dispersed in the first region 20A and the second region 20B and the plurality of quantum dot phosphors 21B dispersed in the third region 20C include different materials from each other. In general, a so-called Cd-based quantum dot phosphor has a higher light resistance than a Cd-free quantum dot phosphor. In the present modification example, the Cd-based quantum dot phosphor is used for the first region 20A and the second region 20B, and the Cd-free quantum dot phosphor is used for the third region 20C.

In this way, by providing the first region 20A in which only the plurality of quantum dot phosphors 21 is dispersed in the resin 23 on the side of the light source unit 10 in the wavelength conversion layer 20, it is possible to use the Cd-free quantum dot phosphors for other regions (for example, the third region 20C farthest from the light source unit 10). Therefore, it is possible to reduce a Cd concentration in the wavelength conversion layer 20, and it is possible to reduce an environment load.

### 8. Modification Example 7

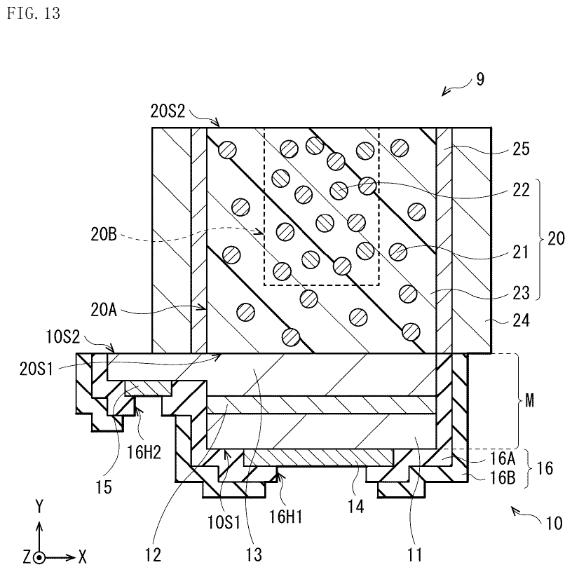

FIG. 13 schematically illustrates an example of a cross-sectional configuration of a light emission device (light emission device 9) according to Modification Example 7 of the present disclosure. The light emission device 9 is preferably used, for example, for the display pixel P of the image display apparatus (for example, image display apparatus 100), similarly to the light emission device 1 according to the above embodiment.

In the above embodiment, an example has been described in which the first region 20A in which only the plurality of quantum dot phosphors 21 is dispersed in the resin 23 and the second region 20B in which both of the plurality of quantum dot phosphors 21 and the plurality of scattering particles 22 are dispersed are provided in this order from the side of the light source unit 10. However, the wavelength conversion layer 20 is not limited to this configuration. For example, as illustrated in FIG. 13, a configuration may be used in which the first region 20A extends toward the side of the light extraction surface 20S2, and the first region 20A is provided around the second region 20B.

In this way, in the present modification example, the concentration of the plurality of quantum dot phosphors 21 in the wavelength conversion layer 20 is changed in the lateral direction. As a result, in plan view, light extraction efficiency relatively increases near the middle of the light emission device 9. Therefore, by combining with a microlens array 32 to be described later, it is possible to improve controllability of light distribution characteristics of the light emission device 9.

### 9. Modification Example 8

FIG. 14 schematically illustrates an example of a cross-sectional configuration of a light emission device (light emission device 1) according to Modification Example 8 of the present disclosure. In the above-described embodiment, an example has been described in which the side surface (surface 20S3) of the wavelength conversion layer 20 is vertical. However, the embodiment is not limited to this example. For example, as illustrated in FIG. 14, the surface 20S3 of the wavelength conversion layer 20 may be formed as an inclined surface extending from a side of the surface 20S1 toward the surface 20S2. As a result, it is possible to further improve the light extraction efficiency of the fluorescence emitted in the wavelength conversion layer 20.

### 10. Modification Example 9

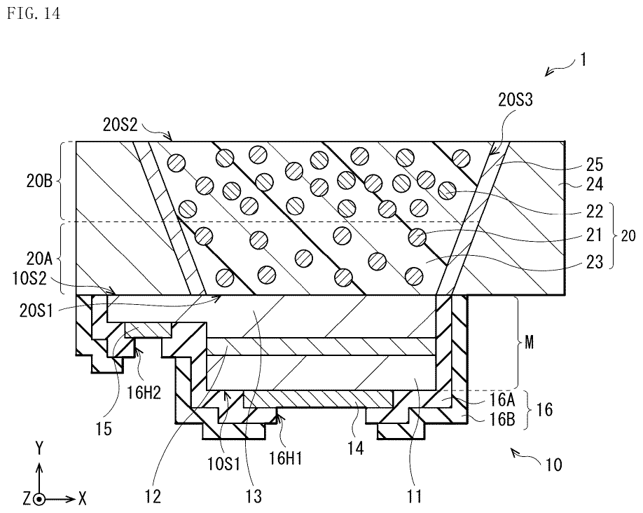

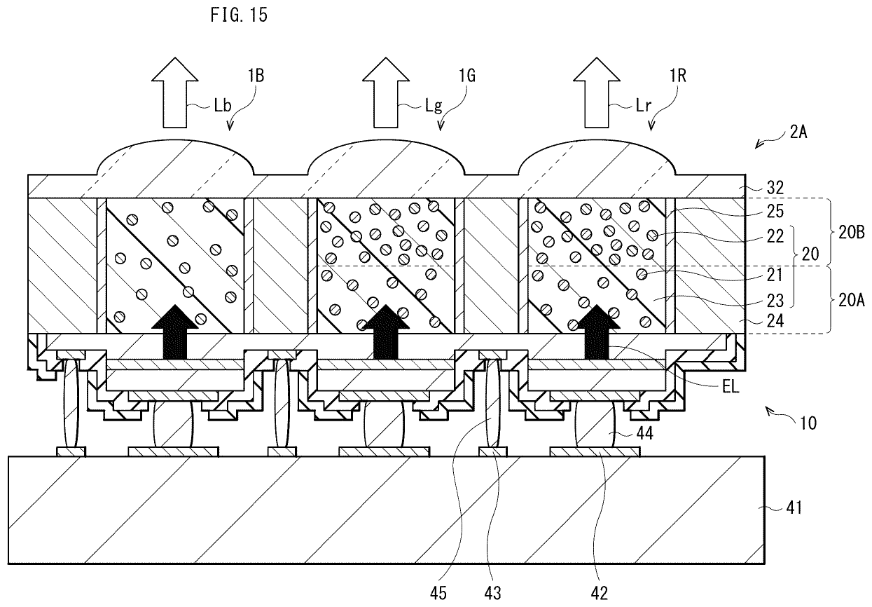

FIG. 15 schematically illustrates an example of a cross-sectional configuration of a light emission unit (light emission unit 2A) according to Modification Example 9 of the present disclosure. The microlens array 32 may be provided on the light extraction surfaces 20S2 of the light emission devices 1R, 1G, and 1B.

The microlens array 32 corresponds to a specific example of a “light distribution control structure” in the present disclosure. As the light distribution control structure, a photonic crystal, a moth-eye structure, a nanoantenna, and a metamaterial may be provided, other than the microlens array 32. As a result, for example, it is possible to enhance a luminance on a low angle side.

### 11. Modification Example 10

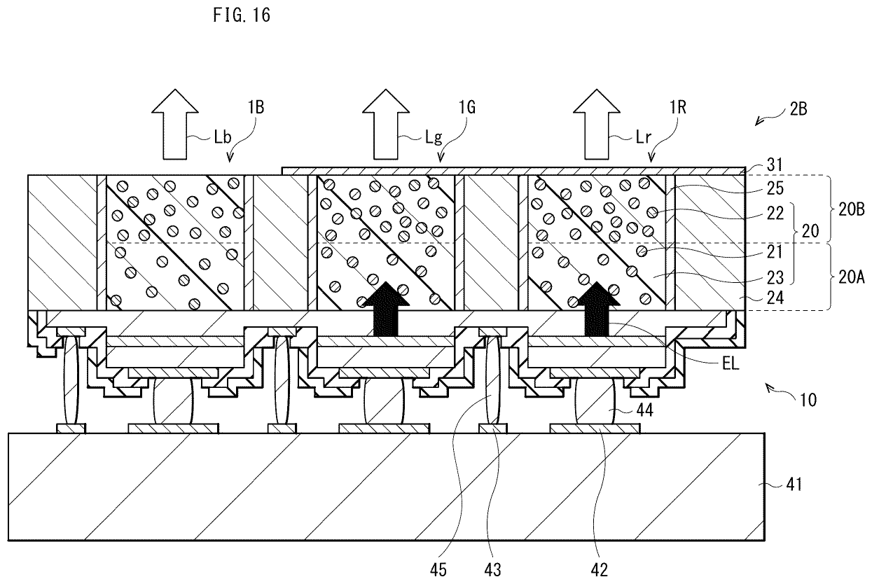

FIG. 16 schematically illustrates an example of a cross-sectional configuration of a light emission unit (light emission unit 2B) according to Modification Example 10 of the present disclosure. In the above-described embodiment, an example has been described in which the plurality of scattering particles 22 is dispersed in a substantially uniform manner in the wavelength conversion layer 20 disposed in the light emission device 1B. However, the embodiment is not limited to this example. For example, the first region 20A and the second region 20B may be provided, as in the light emission devices 1R and 1G, and the concentration of the plurality of scattering particles 22 in the second region 20B may be made to be higher than the concentration of the plurality of scattering particles 22 in the first region 20A. As a result, the rate of the excitation light EL that returns to the light source unit 10 is reduced. Therefore, it is possible to improve light extraction efficiency of the light emission device 1B and to reduce power consumption.

### 12. Modification Example 11

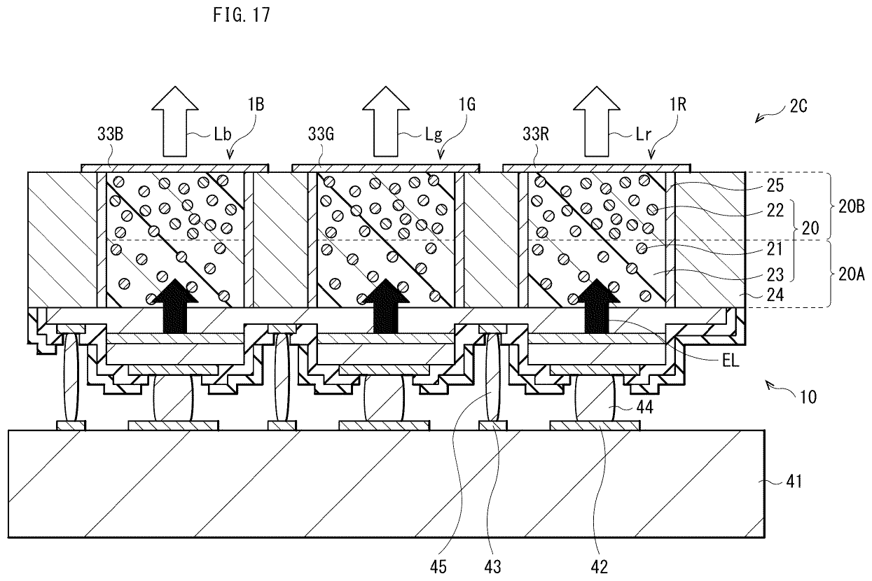

FIG. 17 schematically illustrates an example of a cross-sectional configuration of a light emission unit (light emission unit 2C) according to Modification Example 11 of the present disclosure. In the above-described embodiment, an example has been described in which the corresponding red light Lr, green light Lg, and blue light Lb are emitted from the light emission devices 1R, 1G, and 1B. However, the embodiment is not limited to this example. For example, white light may be emitted from the respective wavelength conversion layers 20 of the light emission devices 1R, 1G, and 1B, and corresponding color filters (red filter 33R, green filter 33G, and blue filter 33B) may be respectively provided on the light extraction surfaces 20S2 of the light emission devices 1R, 1G, and 1B. As a result, it is not necessary to perform a separate coating process of the wavelength conversion layer 20 for each of the color pixels Pr, Pg, and Pb. Accordingly, it is possible to reduce manufacturing cost.

### 13. Modification Example 12

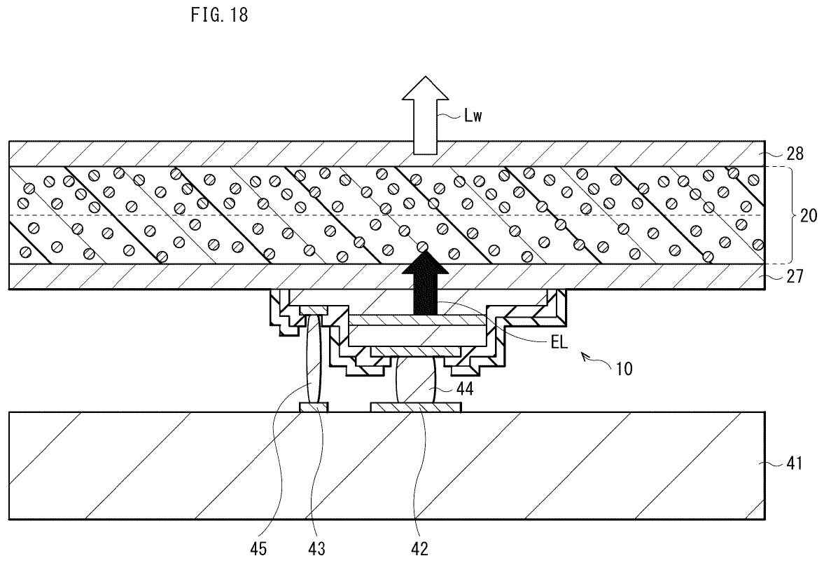

FIG. 18 schematically illustrates another example of the cross-sectional configuration of the wavelength conversion layer 20 according to Modification Example 12 of the present disclosure. In the above-described embodiment, an example has been described in which the wavelength conversion layer 20 is divided by the side wall 24 for each light source unit 10. However, the embodiment is not limited to this example. For example, as illustrated in FIG. 18, white light Lw may be emitted from the wavelength conversion layer 20, and an upper side and a lower side of the wavelength conversion layer 20 may be sealed, for example, with barrier films 27 and 28 having light transparency to form a sheet-like wavelength conversion layer 20. As a result, it is possible to provide a QD sheet with a high luminance. It is possible to use such a QD sheet, for example, as a backlight of a liquid crystal display device.

### 14. Modification Example 13

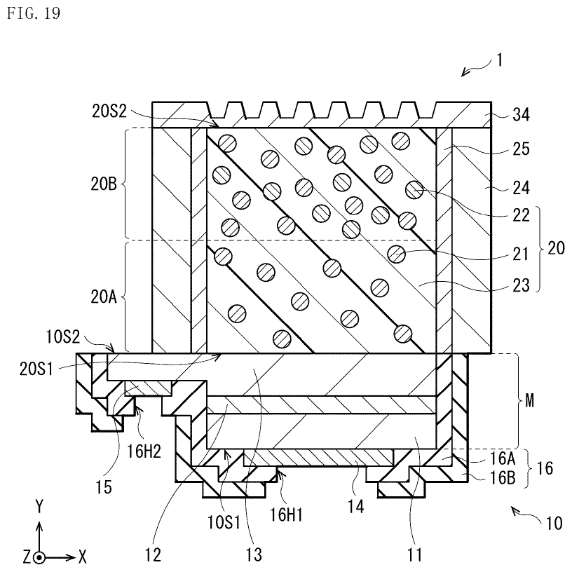

FIG. 19 schematically illustrates an example of a cross-sectional configuration of a light emission device (light emission device 1) according to Modification Example 13 of the present disclosure. On the light extraction surface (surface 20S2) of the wavelength conversion layer 20, a texture structure 34 may be further provided. As a result, it is possible to extract, from the light extraction surface, part of fluorescence emitted from the wavelength conversion layer 20 of which angle is decreased from an angle equal to or larger than a critical angle to an angle smaller than the critical angle while repeating reflection in the wavelength conversion layer 20. Therefore, it is possible to realize a higher luminance in addition to the effects of the above-described embodiment.

It is to be noted that, in the present modification example, an example has been described in which the texture structure 34 is additionally provided on the light extraction surface (surface 20S2) of the wavelength conversion layer 20. However, for example, a texture structure may be formed on the light extraction surface of the wavelength conversion layer 20.

### 15. Application Examples

### Application Example 1

FIG. 20 is a perspective view illustrating an example of a schematic configuration of the image display apparatus (image display apparatus 100). The image display apparatus 100 is a so-called LED display, and the light emission device (for example, light emission device 1) according to the present disclosure is used for the display pixel P. For example, as illustrated in FIG. 20, the image display apparatus 100 includes a display panel 110 and a control circuit 140 that controls driving of the display panel 110.

In the display panel 110, a mounting substrate 120 and a counter substrate 130 are stacked on each other. A surface of the counter substrate 130 serves as a video display surface, the display region 100A is provided in a middle portion, and a frame region 100B that is a non-display region is provided therearound.

FIG. 21 illustrates an example of a wiring layout of a region corresponding to the display region 100A, of a surface of the mounting substrate 120 on a side of the counter substrate 130. For example, as illustrated in FIG. 21, in a region corresponding to the display region 100A in the surface of the mounting substrate 120, a plurality of data wiring lines 1021 extends and is formed in a predetermined direction and is disposed in parallel at a predetermined pitch. In addition, for example, in the region corresponding to the display region 100A in the surface of the mounting substrate 120, a plurality of scan wiring lines 1022 extends and is formed in a direction intersecting with (for example, orthogonal to) the data wiring line 1021 and is disposed in parallel at a predetermined pitch. The data wiring line 1021 and the scan wiring line 1022 include, for example, a conductive material such as Cu.

The scan wiring line 1022 is formed, for example, on an outermost layer, and is formed, for example, on an insulation layer (not illustrated) formed on a base material surface. Note that the base material of the mounting substrate 120 includes, for example, a silicon substrate or a resin substrate, and the insulation layer on the base material includes, for example, SiN, SiO, aluminum oxide (AlO), or a resin material. On the other hand, the data wiring line 1021 is formed in a layer (for example, layer lower than outermost layer) different from the outermost layer including the scan wiring line 1022 and is formed, for example, in the insulation layer on the base material. On a surface of the insulation layer, for example, a black is provided as necessary, in addition to the scan wiring line 1022. The black enhances a contrast and includes a light-absorbing material. For example, the black is formed in at least a non-forming region of pad electrodes 1021B and 1022B to be described later, in the surface of the insulation layer. Note that, it is possible to omit the black, as necessary.

The vicinity of an intersecting portion between the data wiring line 1021 and the scan wiring line 1022 serves as the display pixel P, and the plurality of display pixels P is disposed in the display region 100A, for example, in a matrix. In each display pixel P, for example, the light emission unit 2 including the plurality of light emission devices 1 corresponding to RGB is mounted. In FIG. 21, a case is illustrated in which the three light emission devices 1R, 1G, and 1B configure the single display pixel P, and it is possible to respectively output the red light, the green light, and the blue light from the light emission devices 1R, 1G, and 1B.

Note that the image display apparatus 100 illustrated in FIG. 20 is an example of a passive matrix type image display apparatus. It is possible to apply the light emission device 1 according to the present embodiment to an active matrix type image display apparatus, without limiting to the passive matrix type image display apparatus (image display apparatus 100). Note that, in the active matrix type image display apparatus, for example, the frame region 100B illustrated in FIG. 20 is unnecessary.

In a passive matrix type driving method, because a time allocated to each light emission device is shortened if the number of scan wiring lines increases, an injection current is necessary to be increased along with a decrease in a duty ratio, and there is a possibility that luminance efficiency or a device lifetime is lowered. To avoid this, it is necessary to lower the maximum luminance setting value. Furthermore, due to problems such as a voltage drop or a signal delay caused by a wiring resistance and a parasitic capacitance, for a large screen with a large number of scanning lines or a high-definition image display apparatus, a system for dividing a screen into a plurality of partial screens and performing passive-matrix-driving on the screens in parallel or a system for performing active-driving on the light emission device is adopted. The parallel passive matrix driving makes a structure of an entire display device be more complicated and increases a circuit size, like it is necessary to extract a wiring line to a rear surface for each partial screen to couple the wiring line to a driving circuit, and to divide and parallelize an image signal in accordance with each partial screen. On the other hand, with the active driving system, by holding a signal voltage in pixel unit and providing a voltage-current conversion circuit, it is possible to obtain a higher luminance than the passive matrix driving, in a state where the screen division as described above is not performed or at least the number of divisions is smaller.

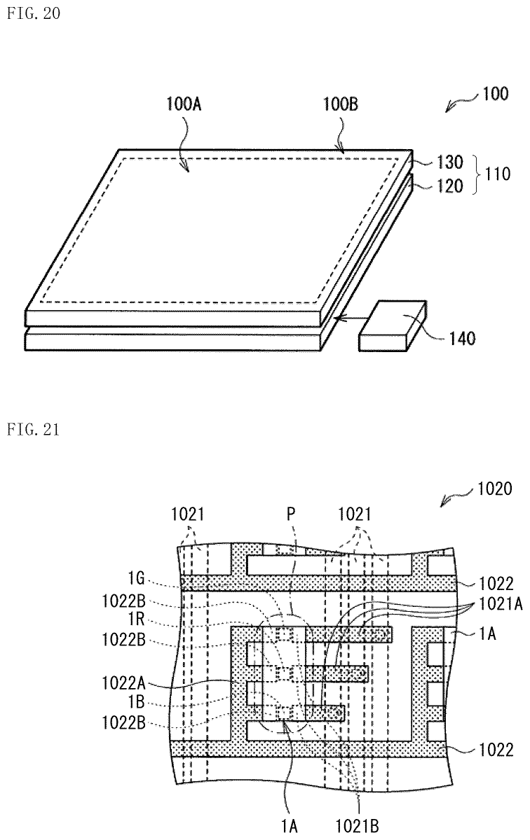

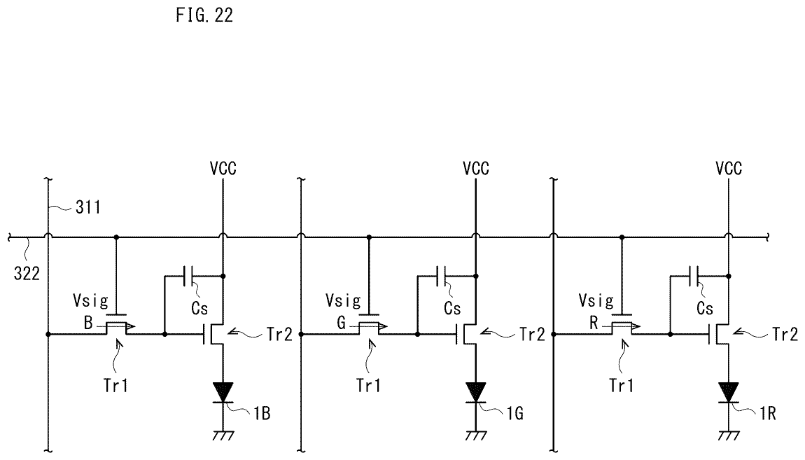

FIG. 22 illustrates an example of a pixel circuit of a general active matrix drive system. In the active matrix drive system, a switching transistor (Tr1), a driving transistor (Tr2), and a capacitative element (Cs) are provided for each display pixel P (near intersecting portion between light emission devices 1R, 1G, and 1B and data wiring line 1021 and scan wiring line 1022). In the active matrix drive system, Vsig is written into the capacitative element using the switching transistor as a switch, and in addition, the light emission device is current-modulated, using the driving transistor as a current source that performs current control with a potential difference obtained by a power source (Vcc)−Vsig.

In the light emission unit 2, for example, a pair of terminal electrodes is provided for each of the light emission devices 1R, 1G, and 1B. Then, the one terminal electrode is, for example, electrically coupled to the data wiring line 1021, and the other terminal electrode is, for example, electrically coupled to the scan wiring line 1022. For example, the terminal electrode is electrically coupled to the pad electrode 1021B at a front end of a branch 1021A provided in the data wiring line 1021. Furthermore, for example, the terminal electrode is electrically coupled to the pad electrode 1022B at a front end of a branch 1022A provided in the scan wiring line 1022.

The pad electrodes 1021B and 1022B are formed, for example, on the outermost layer, and for example, as illustrated in FIG. 21, are provided in a portion where the light emission unit 2 is provided. Here, the pad electrodes 121B and 122B include, for example, a conductive material such as Au (gold).

On the mounting substrate 120, for example, a plurality of pillars (not illustrated) that controls an interval between the mounting substrate 120 and the counter substrate 130 is further provided. The pillar may be provided in an opposing region to the display region 100A or may be provided in an opposing region to the frame region 100B.

The counter substrate 130 includes, for example, a glass substrate, a resin substrate, or the like. Although a surface of the counter substrate 130 on the side of the light emission device 1 may be flat, it is preferable that the surface be a rough surface. The rough surface may be provided across the entire opposing region to the display region 100A or may be provided only on an opposing region to the display pixel P. The rough surface has fine bumps and dips in which light emitted from the display pixel P enters. It is possible to form the bumps and dips on the rough surface, for example, by sandblasting or dry etching.

The control circuit 140 drives each display pixel P (each light emission unit 2) on the basis of a picture signal. The control circuit 140 includes, for example, a data driver that drives the data wiring line 1021 coupled to the display pixel P and a scan driver that drives the scan wiring line 1022 coupled to the display pixel P. For example, as illustrated in FIG. 20, the control circuit 140 may be separately provided from the display panel 110 and coupled to the mounting substrate 120 via a wiring line or may be mounted on the mounting substrate 120.

### Application Example 2

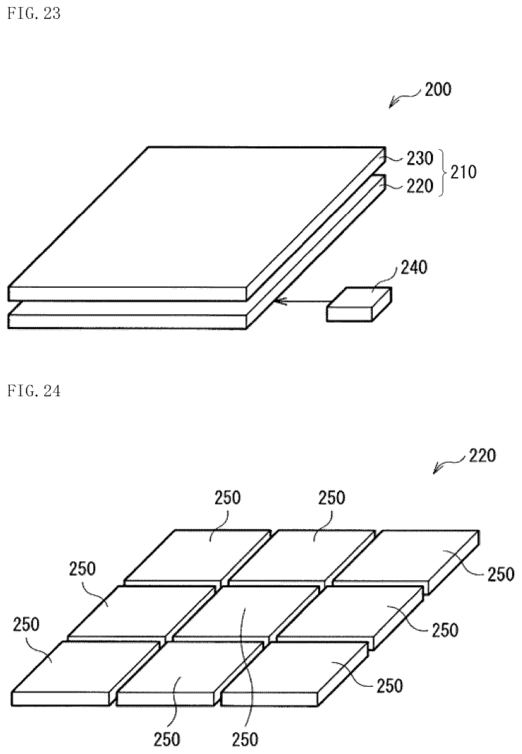

FIG. 23 is a perspective view illustrating another configuration example of the image display apparatus (image display apparatus 200) using the light emission device (for example, light emission device 1) according to the present disclosure. The image display apparatus 200 is a so-called tiling display. For example, as illustrated in FIG. 23, the image display apparatus 200 includes a display panel 210 and a control circuit 240 that controls driving of the display panel 210.

In the display panel 210, a mounting substrate 220 and a counter substrate 230 are stacked on each other. A surface of the counter substrate 230 serves as a video display surface, a display region is provided in a middle portion, and a frame region that is a non-display region is provided therearound (both are not illustrated). The counter substrate 230 is disposed at a position opposing to the mounting substrate 220, for example, with a predetermined gap. Note that, the counter substrate 230 may have contact with a top surface of the mounting substrate 220.

FIG. 24 schematically illustrates an example of a configuration of the mounting substrate 220. For example, as illustrated in FIG. 24, the mounting substrate 220 includes a plurality of unit substrates 250 paved in a tile-like manner. Note that, in FIG. 24, an example is illustrated in which the mounting substrate 220 includes the nine unit substrates 250. However, the number of unit substrates 250 may be equal to or more than 10 and equal to or less than eight.

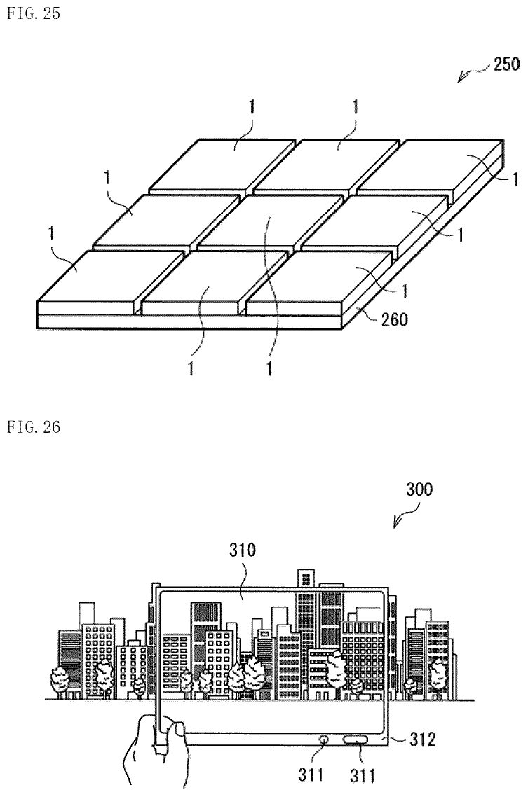

FIG. 25 illustrates an example of a configuration of the unit substrate 250. The unit substrate 250 includes, for example, the plurality of light emission devices 1 paved in a tile-like manner and a support substrate 260 that supports each light emission device 1. Each unit substrate 250 further includes a control substrate (not illustrated). The support substrate 260 includes, for example, a metal frame (metal plate), a wiring substrate, or the like. In a case where the support substrate 260 includes the wiring substrate, it is possible for the support substrate 260 to serve as the control substrate. At this time, at least one of the support substrate 260, the control substrate, or both is electrically coupled to each light emission device 1.

### Application Example 3

FIG. 26 illustrates an appearance of a transparent display 300. The transparent display 300 includes, for example, a display unit 310, an operation unit 311, and a housing 312. For the display unit 310, the light emission device (for example, light emission device 1) according to the present disclosure is used. It is possible for the transparent display 300 to display images and character information as transmitting a background of the display unit 310.

In the transparent display 300, a substrate having light transparency is used as a mounting substrate. Each electrode provided in the light emission device 1 is formed using a conductive material having light transparency, similarly to the mounting substrate. Alternatively, each electrode has a structure that is difficult to be visually recognized by narrowing a wiring line width or thinning a thickness of the wiring line. Furthermore, for example, it is possible for the transparent display 300 to realize black display by stacking a liquid crystal layer including a driving circuit and to switch transmission and black display by controlling a light distribution direction of the liquid crystal.

As described above, the present disclosure has been described using the embodiment, the modification examples 1 to 13, and the application examples. However, the present disclosure is not limited to the above embodiment, and it is possible to make various modifications. For example, in the above example or the like, an example has been described in which the LED chip having the mesa portion M is used as the light source unit 10. However, the shape of the LED chip is not limited to this.

Furthermore, in the above embodiment or the like, although an example has been described in which the LED chip using an inorganic semiconductor is used as the light source unit 10, the light source unit 10 is not limited to this. As the light source unit 10, for example, it is possible to use an LED using an organic semiconductor (OLED) and a semiconductor laser (laser diode: LD).

In addition, it is possible to apply the light emission device (for example, light emission device 1) according to the above embodiment or the like to a smartphone, a television, a laptop computer, an AR/VR device, a projector, a head-up display (HUD), a smart watch, a video wall, or the like, in addition to the application examples 1 to 3 described above.

Note that the effects described herein are examples and not limited, and may be other effects.

Note that the present disclosure may have the following configurations. According to the present technology having the following configuration, in the wavelength conversion layer including the plurality of wavelength conversion materials that converts the first light emitted from the light source unit into the second light in the different wavelength band and the plurality of scattering particles, the absorption coefficient of the first light adjacent to the surface (first surface) on the side of the light source unit is made to be lower than the absorption coefficient of the first light adjacent to the light extraction surface (second surface). This reduces the absorption rate of the excitation light adjacent to the light source unit. Therefore, it is possible to achieve both of the light extraction efficiency and the reliability.
(1)

A light emission device including:
a light source unit that has a light emission surface and emits first light from the light emission surface; and
a wavelength conversion layer that is disposed on a side of the light emission surface of the light source unit, has a first surface disposed to face the light emission surface and a second surface disposed on an opposite side of the first surface, includes a plurality of wavelength conversion materials that converts the first light into second light in a different wavelength band and a plurality of scattering particles, and has a lower absorption coefficient of the first light in a vicinity of the first surface than in a vicinity of the second surface.
(2)

The light emission device according to (1), in which
the wavelength conversion layer includes a first region and a second region in order from a side of the first surface, and
a concentration of the plurality of scattering particles in the first region is lower than a concentration of the plurality of scattering particles in the second region.
(3)

The light emission device according to (2), in which the first region does not include the plurality of scattering particles.
(4)

The light emission device according to any one of (1) to (3), in which
the wavelength conversion layer includes the first region and the second region in order from the side of the first surface, and
a concentration of the plurality of wavelength conversion materials in the first region is lower than a concentration of the plurality of wavelength conversion materials in the second region.
(5)

The light emission device according to any one of (2) to (4), in which the first region extends toward the second surface to surround the second region.
(6)

The light emission device according to any one of (2) to (5), in which the wavelength conversion layer further includes a region that does not include the plurality of wavelength conversion materials and the plurality of scattering particles between the first region and the second region.
(7)

The light emission device according to any one of (1) to (6), in which
the wavelength conversion layer includes the first region, the second region, and a third region in order from the side of the first surface,
the first region does not include the plurality of wavelength conversion materials and includes only the plurality of scattering particles,
the second region does not include the plurality of scattering particles and includes only the plurality of wavelength conversion materials, and
the third region includes the plurality of wavelength conversion materials and the plurality of scattering particles.
(8)

The light emission device according to any one of (1) to (6), in which
the wavelength conversion layer includes the first region, the second region, and a third region in order from the side of the first surface,
the first region does not include the plurality of scattering particles and includes only a plurality of first wavelength conversion materials,
the second region includes the plurality of first wavelength conversion materials and the plurality of scattering particles,
the third region includes a plurality of second wavelength conversion materials and the plurality of scattering particles, and
the first wavelength conversion material has a higher light resistance than the second wavelength conversion material.
(9)

The light emission device according to (8), in which
the first wavelength conversion material is a cadmium-based quantum dot phosphor, and
the second wavelength conversion material is a cadmium-free quantum dot phosphor.
(10)

The light emission device according to any one of (1) to (9), in which
the wavelength conversion layer includes the first region and the second region in order from the side of the first surface, and
a plurality of quantum dots included in the first region has a different material, a different composition, and a different core-shell structure from those of a plurality of quantum dots included in the second region.
(11)

The light emission device according to any one of (1) to (10), in which a light reflection structure is formed on a side surface between the first surface and the second surface of the wavelength conversion layer.
(12)

The light emission device according to (11), in which the side surface is an inclined surface extending from the first surface toward the second surface.
(13)

The light emission device according to any one of (1) to (12), further including an irregular structure on the second surface of the wavelength conversion layer.
(14)

The light emission device according to any one of (1) to (13), further including:
a first light source unit, a second light source unit, and a third light source unit each emitting the first light and serving as the light source unit; and
a first wavelength conversion layer disposed on a side of the light emission surface of the first light source unit, a second wavelength conversion layer disposed on a side of the light emission surface of the second light source unit, and a third wavelength conversion layer disposed on a side of the light emission surface of the third light source unit, the first wavelength conversion layer, the second wavelength conversion layer, and the third wavelength conversion layer each serving as the wavelength conversion layer, in which
the first wavelength conversion layer converts the first light into red light,
the second wavelength conversion layer converts the first light into green light, and
the third wavelength conversion layer transmits the first light or converts the first light into blue light.
(15)

The light emission device according to (14), further including a wavelength selection layer on the second surfaces of at least the first wavelength conversion layer and the second wavelength conversion layer, the wavelength selection layer selectively reflecting the first light.
(16)

The light emission device according to (14) or (15), further including a light distribution control structure on the second surfaces of the first wavelength conversion layer, the second wavelength conversion layer, and the third wavelength conversion layer.
(17)

The light emission device according to (16), in which the light distribution control structure is any one of a microlens array, a photonic crystal, a moth-eye structure, a nanoantenna, and a metamaterial.
(18)

The light emission device according to any one of (1) to (17), further including:
a first light source unit, a second light source unit, and a third light source unit each emitting the first light and serving as the light source unit; and
a first wavelength conversion layer disposed on a side of the light emission surface of the first light source unit, a second wavelength conversion layer disposed on a side of the light emission surface of the second light source unit, and a third wavelength conversion layer disposed on a side of the light emission surface of the third light source unit, the first wavelength conversion layer, the second wavelength conversion layer, and the third wavelength conversion layer each serving as the wavelength conversion layer and converting the first light into white light;
a red filter disposed on the second surface of the first wavelength conversion layer, the red filter selectively transmitting red light;
a green filter disposed on the second surface of the second wavelength conversion layer, the green filter selectively transmitting green light; and
a blue filter disposed on the second surface of the third wavelength conversion layer, the blue filter selectively transmitting blue light.
(19)

The light emission device according to any one of (1) to (18), in which the light source unit is a blue light-emitting diode or an ultraviolet ray light-emitting diode.
(20)

An image display apparatus including
a light emission device including:
a light source unit that has a light emission surface and emits first light from the light emission surface; and
a wavelength conversion layer that is disposed on a side of the light emission surface of the light source unit, has a first surface disposed to face the light emission surface and a second surface disposed on an opposite side of the first surface, includes a plurality of wavelength conversion materials that converts the first light into second light in a different wavelength band and a plurality of scattering particles, and has a lower absorption coefficient of the first light in a vicinity of the first surface than in a vicinity of the second surface.

The present application claims the benefit of Japanese Priority Patent Application No. 2021-185012 filed with the Japan Patent Office on Nov. 12, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A light emission device, comprising:
a light source unit that has a light emission surface and emits first light from the light emission surface; and
a wavelength conversion layer that is disposed on a side of the light emission surface of the light source unit, has a first surface disposed to face the light emission surface and a second surface disposed on an opposite side of the first surface, includes a plurality of wavelength conversion materials that converts the first light into second light in a different wavelength band and a plurality of scattering particles, and has a lower absorption coefficient of the first light in a vicinity of the first surface than in a vicinity of the second surface.

2. The light emission device according to claim 1, wherein
the wavelength conversion layer includes a first region and a second region in order from a side of the first surface, and
a concentration of the plurality of scattering particles in the first region is lower than a concentration of the plurality of scattering particles in the second region.

3. The light emission device according to claim 2, wherein the first region does not include the plurality of scattering particles.

4. The light emission device according to claim 1, wherein
the wavelength conversion layer includes a first region and a second region in order from a side of the first surface, and
a concentration of the plurality of wavelength conversion materials in the first region is lower than a concentration of the plurality of wavelength conversion materials in the second region.

5. The light emission device according to claim 2, wherein the first region extends toward the second surface to surround the second region.

6. The light emission device according to claim 2, wherein the wavelength conversion layer further includes a region that does not include the plurality of wavelength conversion materials and the plurality of scattering particles between the first region and the second region.

7. The light emission device according to claim 1, wherein
the wavelength conversion layer includes a first region, a second region, and a third region in order from a side of the first surface,
the first region does not include the plurality of wavelength conversion materials and includes only the plurality of scattering particles,
the second region does not include the plurality of scattering particles and includes only the plurality of wavelength conversion materials, and
the third region includes the plurality of wavelength conversion materials and the plurality of scattering particles.

8. The light emission device according to claim 1, wherein
the wavelength conversion layer includes a first region, a second region, and a third region in order from a side of the first surface,
the first region does not include the plurality of scattering particles and includes only a plurality of first wavelength conversion materials,
the second region includes the plurality of first wavelength conversion materials and the plurality of scattering particles,
the third region includes a plurality of second wavelength conversion materials and the plurality of scattering particles, and
the first wavelength conversion material has a higher light resistance than the second wavelength conversion material.

9. The light emission device according to claim 8, wherein
the first wavelength conversion material is a cadmium-based quantum dot phosphor, and
the second wavelength conversion material is a cadmium-free quantum dot phosphor.

10. The light emission device according to claim 1, wherein
the wavelength conversion layer includes a first region and a second region in order from a side of the first surface, and
a plurality of quantum dots included in the first region has a different material, a different composition, and a different core-shell structure from those of a plurality of quantum dots included in the second region.

11. The light emission device according to claim 1, wherein a light reflection structure is formed on a side surface between the first surface and the second surface of the wavelength conversion layer.

12. The light emission device according to claim 11, wherein the side surface is an inclined surface extending from the first surface toward the second surface.

13. The light emission device according to claim 1, further comprising an irregular structure on the second surface of the wavelength conversion layer.

14. The light emission device according to claim 1, further comprising:
a first light source unit, a second light source unit, and a third light source unit each emitting the first light and serving as the light source unit; and
a first wavelength conversion layer disposed on a side of the light emission surface of the first light source unit, a second wavelength conversion layer disposed on a side of the light emission surface of the second light source unit, and a third wavelength conversion layer disposed on a side of the light emission surface of the third light source unit, the first wavelength conversion layer, the second wavelength conversion layer, and the third wavelength conversion layer each serving as the wavelength conversion layer, wherein
the first wavelength conversion layer converts the first light into red light,
the second wavelength conversion layer converts the first light into green light, and
the third wavelength conversion layer transmits the first light or converts the first light into blue light.

15. The light emission device according to claim 14, further comprising a wavelength selection layer on the second surfaces of at least the first wavelength conversion layer and the second wavelength conversion layer, the wavelength selection layer selectively reflecting the first light.

16. The light emission device according to claim 14, further comprising a light distribution control structure on the second surfaces of the first wavelength conversion layer, the second wavelength conversion layer, and the third wavelength conversion layer.

17. The light emission device according to claim 16, wherein the light distribution control structure is any one of a microlens array, a photonic crystal, a moth-eye structure, a nanoantenna, and a metamaterial.

18. The light emission device according to claim 1, further comprising:
a first light source unit, a second light source unit, and a third light source unit each emitting the first light and serving as the light source unit;
a first wavelength conversion layer disposed on a side of the light emission surface of the first light source unit, a second wavelength conversion layer disposed on a side of the light emission surface of the second light source unit, and a third wavelength conversion layer disposed on a side of the light emission surface of the third light source unit, the first wavelength conversion layer, the second wavelength conversion layer, and the third wavelength conversion layer each serving as the wavelength conversion layer and converting the first light into white light;
a red filter disposed on the second surface of the first wavelength conversion layer, the red filter selectively transmitting red light;
a green filter disposed on the second surface of the second wavelength conversion layer, the green filter selectively transmitting green light; and
a blue filter disposed on the second surface of the third wavelength conversion layer, the blue filter selectively transmitting blue light.

19. The light emission device according to claim 1, wherein the light source unit is a blue light-emitting diode or an ultraviolet ray light-emitting diode.

20. An image display apparatus, comprising a light emission device including:
a light source unit that has a light emission surface and emits first light from the light emission surface; and
a wavelength conversion layer that is disposed on a side of the light emission surface of the light source unit, has a first surface disposed to face the light emission surface and a second surface disposed on an opposite side of the first surface, includes a plurality of wavelength conversion materials that converts the first light into second light in a different wavelength band and a plurality of scattering particles, and has a lower absorption coefficient of the first light in a vicinity of the first surface than in a vicinity of the second surface.
